(19) United States
(12) Patent Application Publication
(10) Pub. No.: US 2026/0206414 A1
(43) Pub. Date: Jul. 16, 2026

(54) LIGHT-EMITTING ELEMENT AND LIGHT-EMITTING DEVICE

(71) Applicant: Sony Semiconductor Solutions Corporation, Kanagawa (JP)

(72) Inventors: Shoji Sudo, Tokyo (JP); Masahiro Morikawa, Kumamoto (JP); Tomoaki Sawabe, Kanagawa (JP)

(21) Appl. No.: 19/132,624

(22) PCT Filed: Nov. 21, 2023
(86) PCT No.: PCT/JP2023/041829

§ 371 Date: May 23, 2025

(30) Foreign Application Priority Data
Dec. 1, 2022 (JP) 2022-192844

(51) Int. Cl. H10K 50/828; H10K 50/16; H10K 50/17; H10K 102/00; H10K 102/10

(52) U.S. Cl. CPC H10K 50/828; H10K 50/16; H10K 50/171; H10K 2102/10; H10K 2102/351

(57) ABSTRACT

A light-emitting element includes an organic layer including a light-emitting layer, a transparent conductive layer, and a Ca layer disposed between the organic layer and the transparent conductive layer. The Ca layer contains Ca or CaO and a metal material, and the metal material contains at least one of Li, Cs, Rb, K, Ba, Sr, Na, Mg, Yb, a Li compound, a Cs compound, a Rb compound, a K compound, a Ba compound, a Sr compound, a Na compound, a Mg compound, and a Yb compound.

### FIELD

The present disclosure relates to a light-emitting element and a light-emitting device.

### BACKGROUND

Regarding the light-emitting element, for example, Patent Literature 1 discloses a configuration in which a layer containing Ca (calcium) is disposed between an organic layer and a cathode electrode layer.

### CITATION LIST

### Patent Literature

Patent Literature 1: JP 2018-181954 A

### SUMMARY

### Technical Problem

Since Ca is oxidized during manufacture of the light-emitting element, transparency is enhanced, and high luminous efficiency is obtained. On the other hand, an electron injection property is deteriorated by the oxidation of Ca, and reduction in driving voltage is difficult.

One aspect of the present disclosure achieves both high luminous efficiency and reduction in voltage.

### Solution to Problem

A light-emitting element according to one aspect of the present disclosure includes: an organic layer including a light-emitting layer; a transparent conductive layer; and a Ca layer disposed between the organic layer and the transparent conductive layer, wherein the Ca layer contains Ca or CaO and a metal material, and the metal material contains at least one of Li, Cs, Rb, K, Ba, Sr, Na, Mg, Yb, a Li compound, a Cs compound, a Rb compound, a K compound, a Ba compound, a Sr compound, a Na compound, a Mg compound, and a Yb compound.

A light-emitting device according to one aspect of the present disclosure includes a light-emitting element, wherein the light-emitting element includes: an organic layer including a light-emitting layer; a transparent conductive layer; and a Ca layer disposed between the organic layer and the transparent conductive layer, the Ca layer contains Ca or CaO and a metal material, and the metal material contains at least one of Li, Cs, Rb, K, Ba, Sr, Na, Mg, Yb, a Li compound, a Cs compound, a Rb compound, a K compound, a Ba compound, a Sr compound, a Na compound, a Mg compound, and a Yb compound.

### BRIEF DESCRIPTION OF DRAWINGS

FIG. 1 is a diagram illustrating an example of a schematic configuration of a light-emitting element according to a first embodiment.

FIG. 2 is a diagram illustrating an example of a material of a Ca layer.

FIG. 3 is a diagram illustrating a comparative example.

FIG. 4 is a diagram illustrating a comparative example.

FIG. 5 is a diagram illustrating an example of comparison with comparative examples.

FIG. 6 is a diagram illustrating an example of a schematic configuration of a light-emitting element according to a second embodiment.

FIG. 7 is a diagram illustrating an example of a material of a Ca layer.

FIG. 8 is a diagram illustrating an example of a schematic configuration of a light-emitting element according to a third embodiment.

FIG. 9 is a diagram illustrating an example of a material of a metal layer.

FIG. 10 is a diagram illustrating an example of a schematic configuration of a light-emitting element.

FIG. 11 is a diagram illustrating an example of a material of an electron transport layer.

FIG. 12 is a diagram illustrating an example of a schematic configuration of a light-emitting element.

FIG. 13 is a diagram illustrating an example of a schematic configuration of a light-emitting element.

FIG. 14 is a diagram illustrating an example of a schematic configuration of a light-emitting element.

FIG. 15 is a diagram illustrating an example of a method for manufacturing a light-emitting element.

FIG. 16 is a diagram illustrating an application example.

FIG. 17 is a diagram illustrating an example of a schematic configuration of a light-emitting device which is a display device.

### DESCRIPTION OF EMBODIMENTS

Hereinafter, embodiments of the present disclosure will be described in detail with reference to the drawings. Note that in the following embodiments, the same element is denoted by the same reference numeral, and redundant description will be omitted.

The present disclosure will be described according to the following item order.
1. First Embodiment
2. Second Embodiment
3. Third Embodiment
4. More specific embodiments
5. Examples of manufacturing method
6. Application example
7. Examples of effects

### 1. First Embodiment

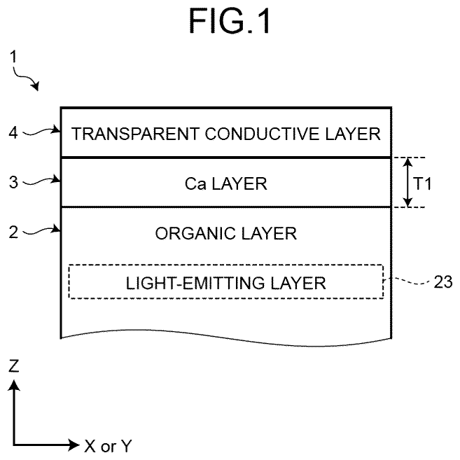

FIG. 1 is a diagram illustrating an example of a schematic configuration of a light-emitting element according to a first embodiment. The light-emitting element 1 has a laminated structure. FIG. 1 schematically illustrates a part of the laminated structure when the light-emitting element 1 is viewed from a side.

FIG. 1 also illustrates an XYZ coordinate system. The X-axis direction and the Y-axis direction (XY plane direction) correspond to a plane direction of each layer. The Z-axis direction corresponds to a laminating direction of each layer. Note that the layer may be a film, and the layer and the film may be appropriately replaced with each other as long as there is no contradiction.

The light-emitting element 1 includes an organic layer 2, a Ca layer 3, and a transparent conductive layer 4. In the Z-axis positive direction, the organic layer 2, the Ca layer 3, and the transparent conductive layer 4 are laminated in this order.

The organic layer 2 contains an organic material. The organic layer 2 may include a plurality of layers, and a light-emitting layer 23 among these layers is illustrated with a reference sign in FIG. 1. As a material of the light-emitting layer 23, various known light-emitting materials (a fluorescent light-emitting material, a phosphorescent light-emitting material, and the like) may be used.

The Ca layer 3 is disposed between the organic layer 2 and the transparent conductive layer 4. In this example, the Ca layer 3 is disposed on the organic layer 2. The Ca layer 3 functions as, for example, a protective layer or an electron injection layer. The Ca layer 3 contains Ca (calcium) and has transparency. The transparency may be understood as the meaning of translucency, and the transparency and the translucency may be appropriately replaced with each other as long as there is no contradiction. The transparency of the Ca layer 3 is obtained by oxidation of Ca in a manufacturing process of the light-emitting element 1. Ca may be contained in the Ca layer 3 in a state of CaO (calcium oxide) by reacting with oxygen. Ca in the Ca layer 3 may be understood as the meaning of CaO as long as there is no contradiction. For example, in the following description, “Ca” related to the Ca layer 3 may be appropriately replaced with “Ca or CaO”. Further details of the Ca layer 3 will be described later.

The transparent conductive layer 4 is disposed on the Ca layer 3 in this example. The transparent conductive layer 4 is a layer having transparency and conductivity. The transparency of the transparent conductive layer 4 may be imparted by oxidation of a material of the transparent conductive layer 4. Specifically, in the manufacturing process of the light-emitting element 1, the material of the transparent conductive layer 4 is oxidized by being exposed to oxygen gas, or oxidized by oxygen contained in the material itself. Examples of the material of the transparent conductive layer 4 include IZO (oxide of indium and zinc), ITO (oxide of indium and tin), AZO (aluminum-doped zinc oxide), GZO (gallium-doped zinc oxide), IGZO (indium/gallium-doped zinc oxide), and ZnO (zinc oxide).

The Ca layer 3 will be further described. The Ca layer 3 contains not only Ca but also a metal material. Examples of the metal material include an alkali metal material and an alkaline earth metal material, and specific examples thereof will be described later. In the first embodiment, Ca and the metal material are mixed in the Ca layer 3. The Ca layer 3 may be a single layer in which Ca and the metal material are mixed.

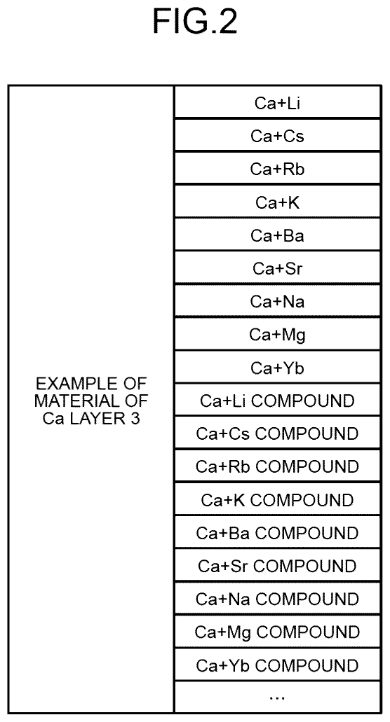

FIG. 2 is a diagram illustrating an example of a material of the Ca layer. “+” described between materials means a mixture of these materials. Examples of the metal material that can be mixed with Ca include Li (lithium), Cs (cesium), Rb (rubidium), K (potassium), Ba (barium), Sr (strontium), Na (sodium), Mg (magnesium), Yb (ytterbium), and compounds thereof. Specific forms of the compounds are not particularly limited. An example of the Li compound is LiF (lithium fluoride). In addition, it is not excluded that two or more exemplified materials are contained in the Ca layer 3 to a possible extent.

A ratio of Ca in the Ca layer 3 is specified using, for example, volumes. In one embodiment, the volumes of Ca in the Ca layer 3 may be 50% or more, 75% or more, 90% or more, or the like. An upper limit value is not particularly limited, and the volumes of Ca in the Ca layer 3 may be, for example, 99.9% or less, 99% or less, or 95% or less, and may be combined with any lower limit value described above.

Returning to FIG. 1, the thickness (length in the Z-axis direction) of the Ca layer 3 is referred to as a thickness T1 in the drawing. In one embodiment, the thickness T1 of the Ca layer 3 may be 10 nm or less, 5 nm or less, or the like. Ca is sufficiently oxidized in a manufacturing process (for example, a sputtering process described later) of the light-emitting element 1 to easily ensure the transparency of the Ca layer 3. A lower limit of the thickness T1 of the Ca layer 3 is not particularly limited, and may be, for example, 0.1 nm or more or 1 nm or more, and may be combined with any upper limit value described above.

In the light-emitting element 1 according to the first embodiment described above, Ca in the Ca layer 3 is oxidized in a manufacturing process thereof, whereby the transparency of the Ca layer 3 is ensured, and therefore high luminous efficiency is obtained. Here, when Ca contained in the Ca layer 3 is oxidized, an electron injection property is deteriorated, and as a result, it is considered that reduction in driving voltage of the light-emitting element 1 is difficult. In this respect, in the light-emitting element 1 according to the first embodiment, since the Ca layer 3 contains the metal material, the electron injection property of the Ca layer 3 is ensured, and thus, reduction in voltage is also possible. For example, in a case where the metal material is LiF, the following reaction occurs, and Li is liberated from the Lif with which the Ca layer 3 is doped, whereby the electron injection property is enhanced.

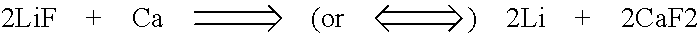

The luminous efficiency and the reduction in voltage will be described with reference to comparative examples.

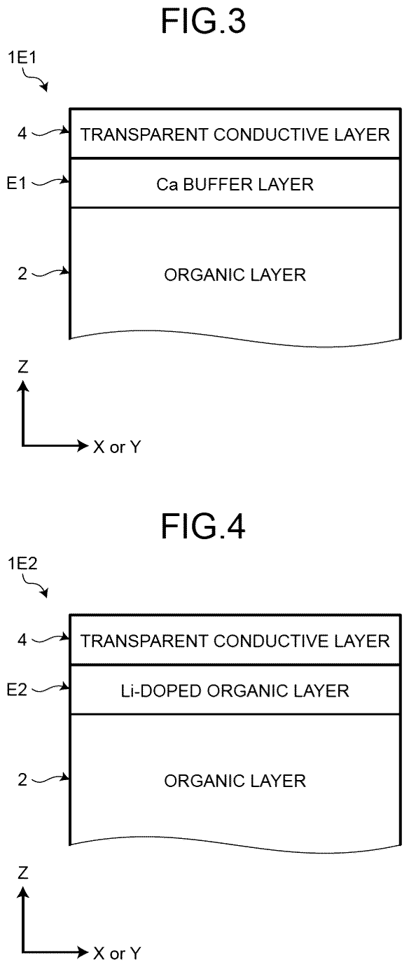

FIGS. 3 and 4 are diagrams illustrating comparative examples. A light-emitting element 1E1 (first comparative example) illustrated in FIG. 3 does not include the Ca layer 3 (FIG. 1) described above, but includes a Ca buffer layer E1. The Ca buffer layer E1 is a layer containing Ca as a main component, but does not contain such a metal material as described above with reference to FIG. 2. An electron injection property is deteriorated by oxidation of Ca, and therefore reduction in driving voltage is difficult. A light-emitting element 1E2 (second comparative example) illustrated in FIG. 4 does not include the Ca layer 3 (FIG. 1) described above, but includes a Li-doped organic layer E2. The Li-doped organic layer E2 is an electron injection layer in which an organic material is doped with Li. Luminous efficiency decreases due to optical absorption caused by interaction between the organic material and Li, and reduction in driving voltage is difficult due to an influence of damage to the organic layer during a sputtering process.

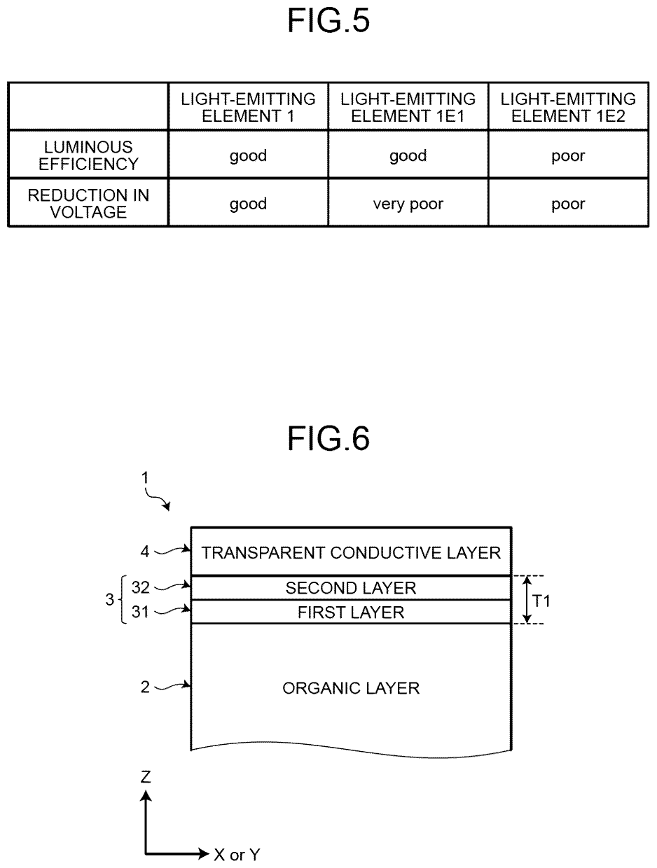

FIG. 5 is a diagram illustrating an example of comparison with comparative examples. As compared with the light-emitting element 1 according to the first embodiment, reduction in voltage of the light-emitting element 1E1 according to the first comparative example is particularly difficult. The driving voltage of the light-emitting element 1E1 can be higher than the driving voltage of the light-emitting element 1 by, for example, about 1.7 V. In the light-emitting element 1E2 according to the second comparative example, the luminous efficiency is low, and reduction in voltage is difficult. When the luminous efficiency of the light-emitting element 1 is 100%, the luminous efficiency of the light-emitting element 1E1 can be, for example, about 96%. The driving voltage of the light-emitting element 1E1 can be higher than the driving voltage of the light-emitting element 1 by, for example, about 0.2 V.

As can be understood from the above-described comparison with comparative examples, the light-emitting element 1 according to the first embodiment can achieve both high luminous efficiency and reduction in voltage.

### 2. Second Embodiment

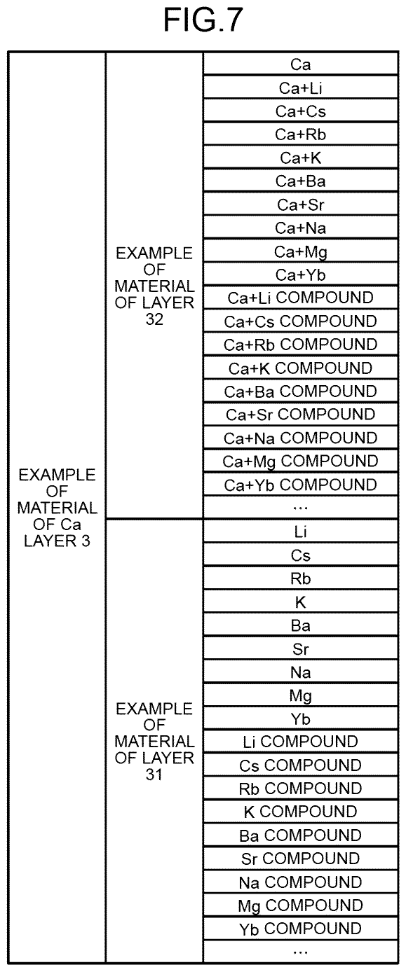

A second embodiment includes a mode in which Ca and a metal material are contained over a plurality of layers in a Ca layer 3. This will be described with reference to FIGS. 6 and 7.

FIG. 6 is a diagram illustrating an example of a schematic configuration of a light-emitting element according to a second embodiment. The Ca layer 3 includes a layer 31 and a layer 32. The layer 31 is a first layer constituting the Ca layer 3. The layer 32 is a second layer constituting the Ca layer 3, and is disposed between the layer 31 and a transparent conductive layer 4. Each of the layer 31 and the layer 32 may be a single layer. In the example illustrated in FIG. 6, the layer 31 is disposed on an organic layer 2, and the layer 32 is disposed on the layer 31. That is, the layer 31 and the layer 32 are laminated in this order in the Z-axis positive direction.

FIG. 7 is a diagram illustrating an example of a material of the Ca layer. The material of each of the layer 31 and the layer 32 included in the Ca layer 3 is exemplified. The layer 31 contains a metal material. Examples of the metal material include Li, Cs, Rb, K, Ba, Sr, Na, Mg, Yb, and compounds thereof as described above. The layer 32 contains Ca.

As illustrated in FIG. 7, the layer 32 may contain not only Ca but also a metal material. In this case, Ca and the metal material may be mixed in the layer 32. Note that some of the combinations of materials of the layer 31 and the layer 32 illustrated in FIG. 7 may be excluded from the configuration of the light-emitting element 1. For example, a configuration in which the layer 31 containing only Li or LiF as a material and the layer 32 containing only Ca as a material are combined may be excluded. The layer 32 in this case may be specified as a layer containing not only Ca but also a metal material, for example, when the layer 31 contains at least Li or LiF.

The volume % of Ca in the Ca layer 3, that is, the volumes of Ca in the whole of the layer 31 and the layer 32 may be 50% or more, 75% or more, 90% or more, or the like as in the first embodiment described above. The same applies to an upper limit value. The thickness T1 of the Ca layer 3, that is, the thickness T1 of the whole of the layer 31 and the layer 32 may be 10 nm or less, 5 nm or less, or the like as in the first embodiment described above. The same applies to a lower limit value.

In one embodiment, the thickness of the layer 31 may be smaller than the thickness of the layer 32. The thickness of the layer 31 may be about ½, about ¼, or the like of the thickness of the layer 32. For example, when the thickness T1 is 5 nm and the thickness of the layer 31 is ¼ of the thickness of the layer 32, the thickness of the layer 31 may be 1 nm and the thickness of the layer 32 may be 4 nm.

In one embodiment, the layer 31 may be an organic layer containing the metal material described above. The layer 31 in this case can function as, for example, an electron transport layer.

In the light-emitting element 1 according to the second embodiment described above, Ca in the Ca layer 3 is oxidized in a manufacturing process thereof, whereby the transparency of the Ca layer 3 is ensured, and therefore high luminous efficiency is obtained as in the first embodiment. In addition, since the Ca layer 3 contains not only Ca but also a metal material, an electron injection property of the Ca layer 3 is ensured. Therefore, both high luminous efficiency and reduction in voltage can be achieved.

### 3. Third Embodiment

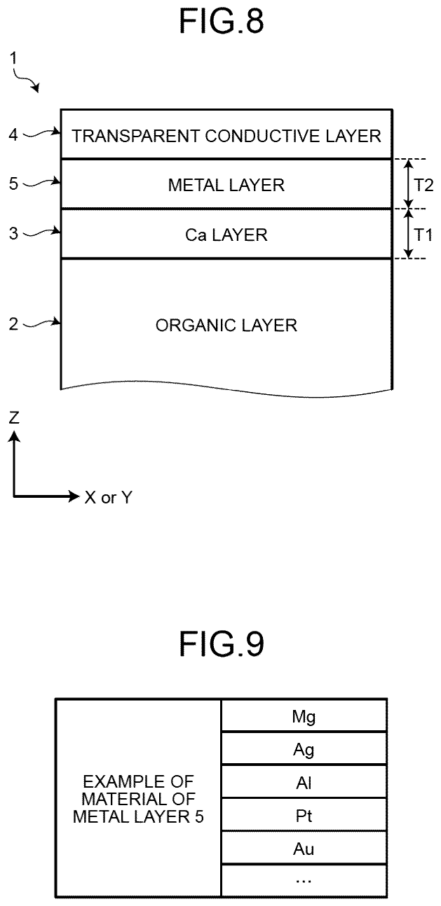

In a third embodiment, a metal layer is further disposed. This will be described with reference to FIGS. 8 and 9.

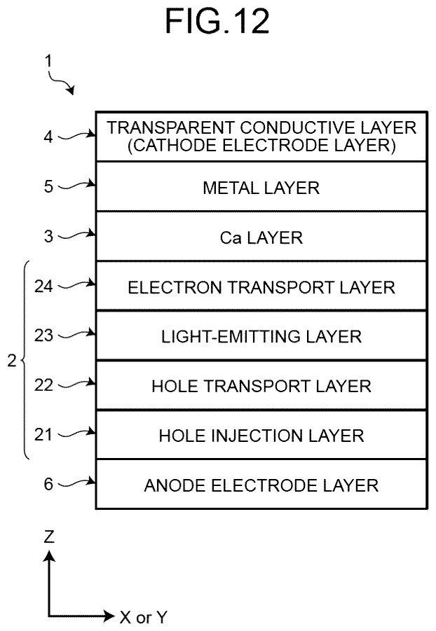

FIG. 8 is a diagram illustrating an example of a schematic configuration of a light-emitting element according to the third embodiment. The light-emitting element 1 further includes a metal layer 5. The metal layer 5 is disposed between a Ca layer 3 and a transparent conductive layer 4. The metal layer 5 is used, for example, to provide a resonance structure. The resonator structure will be described later with reference to FIG. 12. Forming the transparent conductive layer 4 on the metal layer 5 may improve film formability of the metal layer 5.

FIG. 9 is a diagram illustrating an example of a material of the metal layer. Examples of the material of the metal layer 5 include Mg, Ag (silver), Al (aluminum), Pt (platinum), and Au (gold). Two or more materials may be used in combination. Examples of such a material include MgAg.

Returning to FIG. 8, the thickness (length in the Z-axis direction) of the metal layer 5 is referred to as a thickness T2 in the drawing. In one embodiment, the thickness T2 of the metal layer 5 may be 20 nm or less, 10 nm or less, or the like. By making the metal layer 5 thin as described above, a sufficient amount of oxygen can be caused to pass through the metal layer 5 in a manufacturing process of the light-emitting element 1, and Ca in the Ca layer 3 can be oxidized. A lower limit of the thickness T2 of the metal layer 5 is not particularly limited, and may be, for example, 0.1 nm or more or 1 nm or more, and may be combined with any upper limit value described above.

### 4. More Specific Embodiments

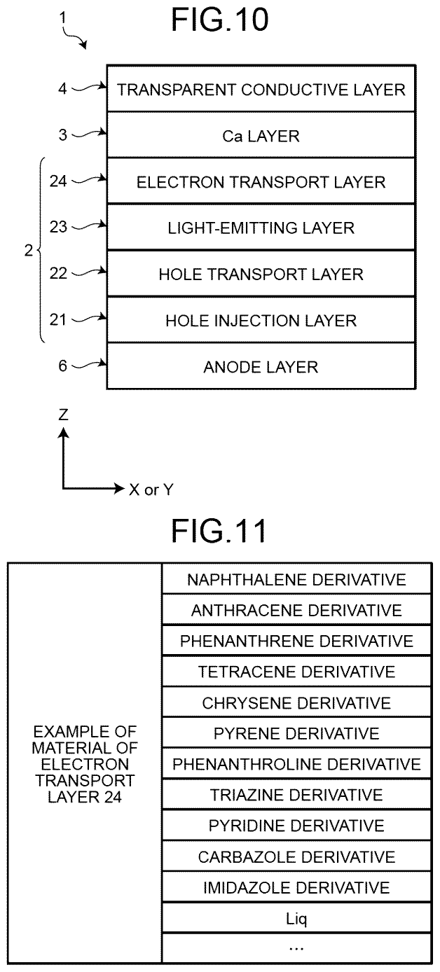

In the first to third embodiments described above, the portions from the organic layer 2 to the transparent conductive layer 4 in the configuration of the light-emitting element 1 have been mainly described. A more specific configuration of the organic layer 2 will be described with reference to FIGS. 10 to 14.

FIG. 10 is a diagram illustrating an example of a schematic configuration of a light-emitting element. The transparent conductive layer 4 is a cathode electrode layer. The light-emitting element 1 further includes an anode electrode layer 6. The anode electrode layer 6 is disposed on a side opposite to the transparent conductive layer 4 with the organic layer 2 and the Ca layer 3 interposed therebetween. In this example, the organic layer 2 is disposed on the anode electrode layer 6. The organic layer 2 includes a hole injection layer 21, a hole transport layer 22, the light-emitting layer 23, and an electron transport layer 24. In the Z-axis positive direction, the hole injection layer 21, the hole transport layer 22, the light-emitting layer 23, and the electron transport layer 24 are laminated in this order.

The hole injection layer 21 and the hole transport layer 22 receive holes from the anode electrode layer 6 and assist hole injection into the light-emitting layer 23. The hole injection layer 21 and the hole transport layer 22 may each contain various known organic electron accepting materials. The light-emitting layer 23 is as described above with reference to FIG. 1.

The electron transport layer 24 may be a layer in contact with (surface contact with) the Ca layer 3 in the organic layer 2. The Ca layer 3 can function as an electron injection layer disposed between the electron transport layer 24 of the organic layer 2 and the transparent conductive layer 4. The Ca layer 3 and the electron transport layer 24 transport electrons injected from the transparent conductive layer 4 to the light-emitting layer 23 and assist electron injection into the light-emitting layer 23. The electron transport layer 24 may contain various known electron transporting materials. This will be described with reference to FIG. 11.

FIG. 11 is a diagram illustrating an example of a material of the electron transport layer. As a material of the electron transport layer 24, a material generally used in organic EL, for example, an aromatic compound such as a naphthalene derivative, an anthracene derivative, a phenanthrene derivative, a tetracene derivative, a chrysene derivative, or a pyrene derivative, or a heterocyclic compound such as a phenanthroline derivative, a triazine derivative, a pyridine derivative, a carbazole derivative, an imidazole derivative, or Liq((8-quinolinolato) lithium) can be used. In addition, the electron transport layer 24 may be a co-vapor deposition type electron transport layer in which the aromatic compound, the heterocyclic compound, an alkali metal or a compound thereof, and an alkaline earth metal or a compound thereof are mixed. An example of a desirable material of the electron transport layer 24 in a case where the Ca layer 3 contains Ca and Li or a Li compound (for example, LiF) is a phenanthroline derivative.

Also in the light-emitting element 1 having the above-described configuration, both high luminous efficiency and reduction in voltage can be achieved as in the first embodiment or the second embodiment described above. Some examples of other configurations capable of obtaining similar effects will be described with reference to FIGS. 12 to 14.

FIGS. 12 to 14 are diagrams illustrating examples of a schematic configuration of a light-emitting element. The light-emitting element 1 illustrated in FIG. 12 is different from the above-described configuration of FIG. 10 in further including the metal layer 5. A structure (cavity structure) in which the light-emitting layer 23 is sandwiched between the metal layer 5 and the anode electrode layer 6 is obtained. A length between the metal layer 5 and the anode electrode layer 6 is designed such that light emitted from the light-emitting layer 23 resonates between the metal layer 5 and the anode electrode layer 6. A resonance condition is expressed by the following formula (1).

$$2 L \times cos θ = ( m - \frac{ϕ}{2 π} ) \times λ \qquad ( 1 )$$

L: optical distance between metal layer 5 and anode electrode layer 6
θ: viewing angle
φ: phase shift amount of light in metal layer 5 and anode electrode layer 6 or light reflecting layer disposed on anode side
λ: wavelength of light from light-emitting layer (emission wavelength)

The layer thickness of the organic layer 2 and the layer thickness of the transparent conductive layer 4 may be adjusted so as to obtain the optical distance L satisfying the above formula (1) according to the emission wavelength A. In addition, in a case where the anode side has a configuration of reflection layer/optical adjustment layer/ITO or the like, it is necessary to consider a phase shift in the reflection layer. With such a resonance structure, it is possible to improve light-emitting performance of the light-emitting element 1 by increasing spectral intensity of light extracted through the transparent conductive layer 4, narrowing a half-value width, or the like.

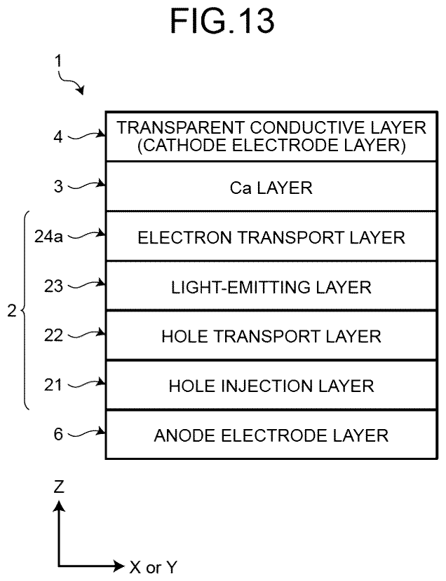

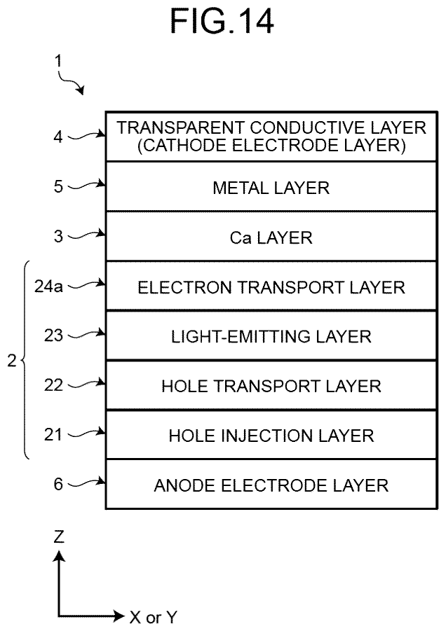

The light-emitting elements 1 illustrated in FIGS. 13 and 14 are different from the above-described configurations of FIGS. 10 and 12 in that the organic layer 2 includes an electron transport layer 24a instead of the electron transport layer 24. The electron transport layer 24a contains not only the material (for example, a phenanthroline derivative) described above with reference to FIG. 11 but also a metal material. Examples of the metal material include Li, Li, Cs, Rb, K, Ba, Sr, Na, Mg, Yb, and compounds thereof as described above. The electron transport layer 24a is obtained by partially diffusing the metal material in the Ca layer 3 into a layer below the Ca layer 3 (on the Z-axis negative direction side) in a manufacturing process. There is a possibility that an electron transporting property of the electron transport layer 24a is enhanced because the electron transport layer 24a contains the metal material.

Note that, as mentioned in the second embodiment above, when the layer 31 of the Ca layer 3 functions as an electron transport layer, the electron transport layer 24 or the electron transport layer 24a may be regarded not as a component of the organic layer 2 but as a component of the Ca layer 3.

### 5. Examples of Manufacturing Method

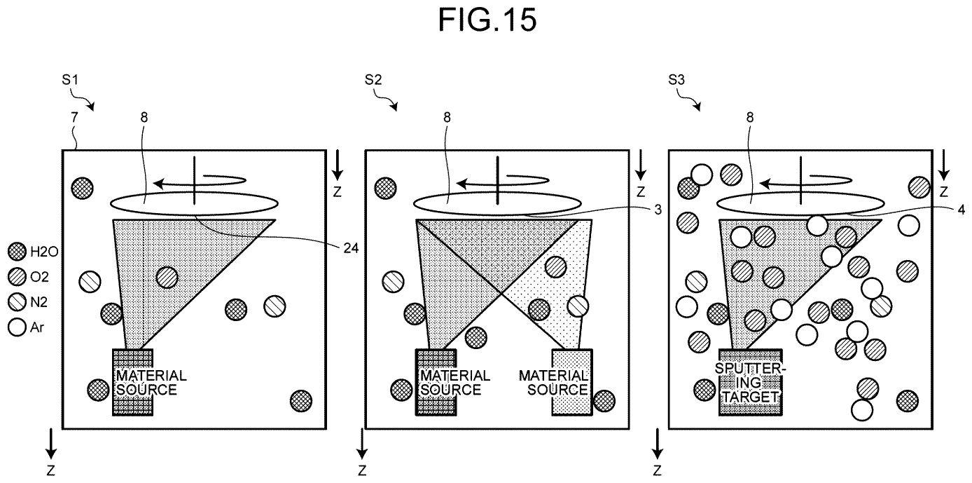

Various known methods may be used for manufacturing the light-emitting element 1. A manufacturing process mainly related to the Ca layer 3 and its periphery will be described with reference to FIG. 15.

FIG. 15 is a diagram illustrating an example of a method for manufacturing a light-emitting element. As a premise, a structure in which the anode electrode layer 6, the hole injection layer 21, the hole transport layer 22, and the light-emitting layer 23 are laminated is obtained by various known methods. In a chamber 7, vapor deposition and sputtering are performed on the structure. The structure to be subjected to vapor deposition and sputtering is referred to as a target 8 in the drawing. Note that the direction in the Z-axis direction is opposite to that in the previous drawings.

In Step S1, a material of the electron transport layer 24 is vapor-deposited onto the target 8 from a material source (for example, a crucible). As a result, the target 8 including the electron transport layer 24 is obtained. In addition to nitrogen (N₂), a certain amount of moisture (H₂O) and oxygen (O₂) may be present in the chamber 7. Note that the amount of oxygen may be very small.

In Step S2, a material of the Ca layer 3 is vapor-deposited onto the target 8 from a material source. As a result, the target 8 including the Ca layer 3 is obtained. In this example, materials from two material sources are mixed in the chamber 7 and vapor-deposited onto the target 8. One of the two material sources supplies Ca, and the other material source supplies LiF (an example of the metal material). By bringing Ca into contact with LiF by a means of co-vapor deposition or lamination, LiF is reduced to Li by Ca. It is considered that it is effective to increase a contact area for promoting the reduction reaction, and in this sense, it can be said that co-vapor deposition is more desirable than lamination. A similar reaction is considered to occur between Li, Cs, Rb, K, Ba, Sr, Na, Mg, and Yb compounds and Ca. In addition, as in the previous Step S1, a certain amount of moisture and oxygen may be present in the chamber 7 in addition to nitrogen. Therefore, oxidation of Li, Cs, Rb, K, Ba, Sr, Na, Mg, and Yb may occur during film formation, and the original electron injection property may be impaired. The impaired electron injection property can be improved by reducing the metal oxides with Ca.

In Step S3, a material of the transparent conductive layer 4 is sputtered onto the target 8 from a sputtering target. As a result, the target 8 including the transparent conductive layer 4, that is, the light-emitting element 1 is obtained. In addition to nitrogen, a certain amount of moisture and a large amount of oxygen may be present in the chamber 7. Argon (Ar) contained in a sputtering gas is also exemplified. The large amount of oxygen is derived from a process gas for adjusting the amount of oxygen in the transparent conductive layer 4 or oxygen released from the sputtering target itself in the process of sputtering. Since the large amount of oxygen is present, Ca in the previously formed Ca layer 3 reacts with the gas to be oxidized, and the Ca layer 3 becomes transparent. For example, in this way, it is possible to obtain the light-emitting element 1 including the Ca layer 3 in which Ca and a metal material (Li or LiF in this example) are mixed.

Note that, when the Ca layer 3 is divided into the layer 31 and the layer 32 as in the second embodiment described above, vapor deposition of the material of the layer 31 and vapor deposition of the material of the layer 32 may be sequentially performed in Step S2.

### 6. Application Example

The light-emitting element 1 described above can be incorporated in various light-emitting devices and used. This will be described with reference to FIG. 15.

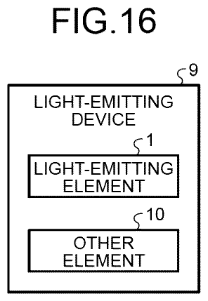

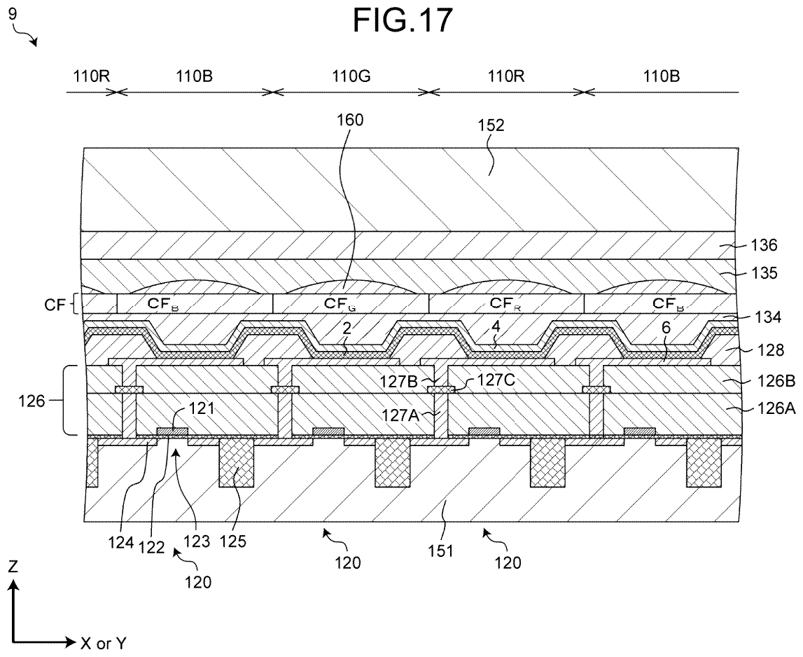

FIG. 16 is a diagram illustrating an application example. An illustrated light-emitting device 9 includes the light-emitting element 1 described above and another element 10. Examples of the light-emitting device 9 include a display device and a lighting device. The light-emitting element 1 is incorporated in the light-emitting device 9 in a mode suitable for a purpose of the light-emitting device 9. For example, when the light-emitting device 9 is a display device, the light-emitting element 1 may be incorporated in the light-emitting device 9 so as to constitute a pixel array. When the light-emitting device 9 is a lighting device, the light-emitting element 1 may be incorporated in the light-emitting device 9 so as to constitute a light source. The other element 10 is, for example, a drive circuit of the light-emitting element 1, a control circuit thereof, a signal processing circuit (including a processor) thereof, or an interface with the outside, but is not limited thereto. In the light-emitting device 9 including the light-emitting element 1, as described above, both luminous efficiency and reduction in voltage are achieved. Therefore, light-emitting performance of the light-emitting device 9 can be improved. As an example, a configuration in a case where the light-emitting device 9 is a display device will be further described with reference to FIG. 17.

FIG. 17 is a diagram illustrating an example of a schematic configuration of a light-emitting device which is a display device. A partial cross section of the light-emitting device 9 is schematically illustrated. The organic layer 2 is disposed between a first substrate 151 and a second substrate 152. Light from the organic layer 2 is output to the outside of the light-emitting device 9 via the second substrate 152.

The light-emitting device 9 includes a plurality of sub-pixels corresponding to colors. A sub-pixel corresponding to red is referred to as a sub-pixel 110R in the drawing. A sub-pixel corresponding to green is referred to as a sub-pixel 110G in the drawing. A sub-pixel corresponding to blue is referred to as a sub-pixel 110B in the drawing. The organic layer 2 is shared by the plurality of sub-pixels, and for example, the sub-pixel 110R, the sub-pixel 110G, and the sub-pixel 110B are obtained by a combination of the organic layer 2 that emits white light and a color filter (described later) corresponding to each color.

The anode electrode layer 6 functions as a first electrode disposed for each sub-pixel. The transparent conductive layer 4 functions as a common electrode (second electrode) commonly used for the plurality of sub-pixels. The anode electrode layer 6, the organic layer 2, and the transparent conductive layer 4 are sequentially formed on a base 126 and an insulating layer 128 formed on the first substrate 151. The base 126 has an insulating property, and examples of a material of the base 126 include SiO2, SiN, and SiON.

In the example illustrated in FIG. 17, a protective layer 134 is formed on the transparent conductive layer 4 so as to cover the transparent conductive layer 4. Examples of a material of the protective layer 134 include SiN. A color filter layer CF (wavelength selecting unit) made of a known material is formed on the protective layer 134 by a known method. The color filter layer CF has a color filter CFR that allows red light to pass therethrough in the sub-pixel 110R, a color filter CF; that allows green light to pass therethrough in the sub-pixel 110G, and a color filter CFs that allows blue light to pass therethrough in the sub-pixel 110B.

A flattening layer 135 is formed on the color filter layer CF. The flattening layer 135 and the second substrate 152 are bonded to each other, for example, with a resin layer (sealing resin layer) 136 interposed therebetween. Examples of a material of the sealing resin layer 136 include a thermosetting adhesive such as an acrylic adhesive, an epoxy-based adhesive, a urethane-based adhesive, a silicone-based adhesive, or a cyanoacrylate-based adhesive, and an ultraviolet-curable adhesive. The color filter layer CF is an on-chip color filter layer (OCCF), and a distance between the organic layer 2 and the color filter layer CF can be thereby shortened. It is possible to suppress occurrence of color mixing by entrance of light emitted from the organic layer 2 into an adjacent color filter of another color. In some cases, the flattening layer 135 may be omitted, and the color filter layer CF may be bonded to the second substrate 152 via the sealing resin layer 136.

A lens member (on-chip microlens) 160 which is an optical path control unit through which light emitted from the organic layer 2 passes is disposed above the organic layer 2, specifically, on the color filter layer CF disposed on the protective layer 134. The protective layer 134 and the lens member 160 are covered with the flattening layer 135, and the flattening layer 135 and the second substrate 152 are bonded to each other via, for example, the resin layer (sealing resin layer) 136.

The lens member 160 can be manufactured, for example, by the following method. That is, a lens member forming layer for forming the lens member 160 is formed on the color filter layer CF, and a resist material layer is formed thereon. Then, the resist material layer is patterned and further subjected to heat treatment to form the resist material layer into a lens member shape. Next, the resist material layer and the lens member forming layer are etched back to transfer the shape formed in the resist material layer to the lens member forming layer. In this way, the lens member 160 can be obtained.

A drive circuit is disposed under or below the base 126. The drive circuit includes, for example, a transistor 120 (MOSFET or the like) formed on a silicon semiconductor substrate constituting the first substrate 151. The transistor 120 and the anode electrode layer 6 are connected to each other via, for example, a contact hole (contact plug) 127A, a pad portion 1270, and a contact hole (contact plug) 127B formed in the base 126.

The transistor 120 includes a gate insulating layer 122 formed on the first substrate 151, a gate electrode 121 formed on the gate insulating layer 122, a source/drain region 124 formed on the first substrate 151, a channel formation region 123 formed between the source/drain regions 124, and an element isolation region 125 surrounding the channel formation region 123 and the source/drain region 124.

In the example illustrated in FIG. 17, the base 126 includes a lower interlayer insulating layer 126A and an upper interlayer insulating layer 126B. The transistor 120 and the anode electrode layer 6 are electrically connected to each other via the contact plug 127A disposed in the lower interlayer insulating layer 126A, the pad portion 127C disposed on the lower interlayer insulating layer 126A, and the contact plug 127B disposed in the upper interlayer insulating layer 126B.

The transparent conductive layer 4 is connected to the drive circuit (light-emitting element driving unit) via a contact hole (contact plug) (not illustrated) formed in the base 126 at an outer peripheral portion (specifically, an outer peripheral portion of a pixel array unit) of the light-emitting device 9. In the outer peripheral portion of the light-emitting device 9, an auxiliary electrode connected to the anode electrode layer 6 may be disposed below the transparent conductive layer 4, and the auxiliary electrode may be connected to the drive circuit.

For example, the light-emitting element 1 (organic layer 2, transparent conductive layer 4, anode electrode layer 6, and the like) described above may be incorporated in the light-emitting device 9 having the above configuration.

### 7. Examples of Effects

The techniques described above are specified as follows, for example. One of the disclosed techniques is the light-emitting element 1. As described with reference to FIGS. 1, 2, 6 to 14, and the like, the light-emitting element 1 includes the organic layer 2 including the light-emitting layer 23, the transparent conductive layer 4, and the Ca layer 3 disposed between the organic layer 2 and the transparent conductive layer 4. The Ca layer 3 contains Ca (or CaO) and a metal material, and the metal material contains at least one of Li, Cs, Rb, K, Ba, Sr, Na, Mg, Yb, a Li compound, a Cs compound, a Rb compound, a K compound, a Ba compound, a Sr compound, a Na compound, a Mg compound, and a Yb compound.

In the above light-emitting element 1, Ca in the Ca layer 3 is oxidized in a manufacturing process thereof, whereby transparency of the Ca layer 3 is ensured, and therefore high luminous efficiency can be obtained. In addition, by inclusion of a metal material in the Ca layer 3, an electron injection property of the Ca layer 3 is ensured, and therefore reduction in voltage is also possible. Therefore, both high luminous efficiency and reduction in voltage can be achieved.

As described with reference to FIGS. 1, 2, 6, 7, and the like, the volumes of Ca (or CaO) in the Ca layer 3 may be 50% or more, more specifically 75% or more, and still more specifically 90% or more. For example, by inclusion of Ca (or CaO) and the metal material at such a ratio, transparency and an electron injection property can be suitably ensured.

As described with reference to FIGS. 1, 6, and the like, the thickness T1 of the Ca layer 3 may be 10 nm or less, and more specifically, 5 nm or less. For example, with such a thickness T1 of the Ca layer 3, Ca can be sufficiently oxidized in a manufacturing process of the light-emitting element 1 to ensure transparency of the Ca layer 3.

As described with reference to FIGS. 1, 2, and the like, Ca (or CaO) and the metal material may be mixed in the Ca layer 3. Alternatively, as described with reference to FIGS. 6, 7, and the like, the Ca layer 3 may include the layer 31 (first layer) and the layer 32 (second layer) disposed between the layer 31 and the transparent conductive layer 4, the layer 31 may include a metal material, and the layer 32 may include Ca (or CaO). The layer 31 may be an organic layer containing a metal material. For example, by using such a Ca layer 3, both high luminous efficiency and reduction in voltage can be achieved.

As described with reference to FIGS. 8, 9, 12, 14, and the like, the light-emitting element 1 may include the metal layer 5 disposed between the Ca layer 3 and the transparent conductive layer 4, and the metal layer 5 may contain at least one of Mg, Ag, Al, Pt, and Au. The transparent conductive layer 4 is a cathode electrode layer, and the light-emitting element 1 may include the anode electrode layer 6 disposed on a side opposite to the transparent conductive layer 4 with the organic layer 2 and the Ca layer 3 interposed therebetween. By using such a resonance structure, light-emitting performance of the light-emitting element 1 can be improved.

As described with reference to FIG. 8 and the like, the thickness T2 of the metal layer 5 may be 20 nm or less, and more specifically, 10 nm or less. For example, by using such a thin metal layer 5, Ca in the Ca layer 3 can be sufficiently oxidized in a manufacturing process of the light-emitting element 1 even when the metal layer 5 is present, and transparency of the Ca layer 3 can be ensured.

The light-emitting device 9 described with reference to FIG. 16 and the like is also one of the disclosed techniques. The light-emitting device 9 includes the light-emitting element 1 described above. Since both high luminous efficiency and reduction in voltage are achieved in the light-emitting element 1, light-emitting performance of the light-emitting device 9 can be improved.

Note that the effects described in the present disclosure are merely examples, and the present technique is not limited to the disclosed contents. There may be other effects.

Although the embodiments of the present disclosure have been described above, the technical scope of the present disclosure is not limited to the above-described embodiments as they are, and various modifications can be made without departing from the gist of the present disclosure. In addition, components of different embodiments and modifications may be appropriately combined with each other.

Note that the present technique can also have the following configurations.
(1) A light-emitting element comprising:
   an organic layer including a light-emitting layer;
   a transparent conductive layer; and
   a Ca layer disposed between the organic layer and the transparent conductive layer, wherein
   the Ca layer contains Ca or CaO and a metal material, and
   the metal material contains at least one of Li, Cs, Rb, K, Ba, Sr, Na, Mg, Yb, a Li compound, a Cs compound, a Rb compound, a K compound, a Ba compound, a Sr compound, a Na compound, a Mg compound, and a Yb compound.
(2) The light-emitting element according to (1), wherein
   a volumes of the Ca or CaO in the Ca layer is 50% or more.
(3) The light-emitting element according to (1) or (2), wherein
   a volume of the Ca or CaO in the Ca layer is 75% or more.
(4) The light-emitting element according to any one of (1) to (3), wherein
   a volumes of the Ca or CaO in the Ca layer is 90% or more.
(5) The light-emitting element according to any one of (1) to (4), wherein
   the Ca layer has a thickness of 10 nm or less.
(6) The light-emitting element according to any one of (1) to (5), wherein
   the Ca layer has a thickness of 5 nm or less.
(7) The light-emitting element according to any one of (1) to (6), wherein
   the metal material contains the Li or the Li compound.
(8) The light-emitting element according to any one of (1) to (7), wherein
   the metal material contains the Li compound, and
   the Li compound contains LiF.
(9) The light-emitting element according to any one of (1) to (8), wherein
   the Ca or CaO and the metal material are mixed in the Ca layer.
(10) The light-emitting element according to any one of (1) to (8), wherein
   the Ca layer includes a first layer and a second layer disposed between the first layer and the transparent conductive layer,
   the first layer contains the metal material, and
   the second layer contains the Ca or CaO.
(11) The light-emitting element according to (10), wherein
   the first layer is an organic layer containing the metal material.
(12) The light-emitting element according to any one of (1) to (11), comprising a metal layer disposed between the Ca layer and the transparent conductive layer, wherein
   the metal layer contains at least one of Mg, Ag, Al, Pt, and Au.
(13) The light-emitting element according to (12), wherein
   the metal layer contains the Ag.
(14) The light-emitting element according to (13), wherein
   the transparent conductive layer is a cathode electrode layer, and
   the light-emitting element includes an anode electrode layer disposed on a side opposite to the transparent conductive layer with the organic layer and the Ca layer interposed therebetween.
(15) The light-emitting element according to (13) or (14), wherein
   the metal layer has a thickness of 20 nm or less.
(16) The light-emitting element according to any one of (13) to (15), wherein
   the metal layer has a thickness of 10 nm or less.
(17) A light-emitting device comprising a light-emitting element, wherein
   the light-emitting element includes:
   an organic layer including a light-emitting layer;
   a transparent conductive layer; and
   a Ca layer disposed between the organic layer and the transparent conductive layer,
   the Ca layer contains Ca or CaO and a metal material, and
   the metal material contains at least one of Li, Cs, Rb, K, Ba, Sr, Na, Mg, Yb, a Li compound, a Cs compound, a Rb compound, a K compound, a Ba compound, a Sr compound, a Na compound, a Mg compound, and a Yb compound.

### REFERENCE SIGNS LIST

1 LIGHT-EMITTING ELEMENT
2 ORGANIC LAYER
21 HOLE INJECTION LAYER
22 HOLE TRANSPORT LAYER
23 LIGHT-EMITTING LAYER
24 ELECTRON TRANSPORT LAYER
24a ELECTRON TRANSPORT LAYER
3 Ca LAYER
4 TRANSPARENT CONDUCTIVE LAYER
5 METAL LAYER
6 ANODE ELECTRODE LAYER
7 CHAMBER
8 TARGET
9 LIGHT-EMITTING DEVICE
10 OTHER ELEMENT

1. A light-emitting element comprising:
an organic layer including a light-emitting layer;
a transparent conductive layer; and
a Ca layer disposed between the organic layer and the transparent conductive layer, wherein
the Ca layer contains Ca or CaO and a metal material, and
the metal material contains at least one of Li, Cs, Rb, K, Ba, Sr, Na, Mg, Yb, a Li compound, a Cs compound, a Rb compound, a K compound, a Ba compound, a Sr compound, a Na compound, a Mg compound, and a Yb compound.

2. The light-emitting element according to claim 1, wherein
a volume of the Ca or CaO in the Ca layer is 50% or more.

3. The light-emitting element according to claim 1, wherein
a volumes of the Ca or CaO in the Ca layer is 75% or more.

4. The light-emitting element according to claim 1, wherein
a volume % of the Ca or CaO in the Ca layer is 90% or more.

5. The light-emitting element according to claim 1, wherein
the Ca layer has a thickness of 10 nm or less.

6. The light-emitting element according to claim 1, wherein
the Ca layer has a thickness of 5 nm or less.

7. The light-emitting element according to claim 1, wherein
the metal material contains the Li or the Li compound.

8. The light-emitting element according to claim 1, wherein
the metal material contains the Li compound, and
the Li compound contains LiF.

9. The light-emitting element according to claim 1, wherein
the Ca or CaO and the metal material are mixed in the Ca layer.

10. The light-emitting element according to claim 1, wherein
the Ca layer includes a first layer and a second layer disposed between the first layer and the transparent conductive layer,
the first layer contains the metal material, and
the second layer contains the Ca or CaO.

11. The light-emitting element according to claim 10, wherein
the first layer is an organic layer containing the metal material.

12. The light-emitting element according to claim 1, comprising a metal layer disposed between the Ca layer and the transparent conductive layer, wherein
the metal layer contains at least one of Mg, Ag, Al, Pt, and Au.

13. The light-emitting element according to claim 12, wherein
the metal layer contains the Ag.

14. The light-emitting element according to claim 13, wherein
the transparent conductive layer is a cathode electrode layer, and
the light-emitting element includes an anode electrode layer disposed on a side opposite to the transparent conductive layer with the organic layer and the Ca layer interposed therebetween.

15. The light-emitting element according to claim 13, wherein
the metal layer has a thickness of 20 nm or less.

16. The light-emitting element according to claim 13, wherein
the metal layer has a thickness of 10 nm or less.

17. A light-emitting device comprising a light-emitting element, wherein
the light-emitting element includes:
an organic layer including a light-emitting layer;
a transparent conductive layer; and
a Ca layer disposed between the organic layer and the transparent conductive layer,
the Ca layer contains Ca or CaO and a metal material, and
the metal material contains at least one of Li, Cs, Rb, K, Ba, Sr, Na, Mg, Yb, a Li compound, a Cs compound, a Rb compound, a K compound, a Ba compound, a Sr compound, a Na compound, a Mg compound, and a Yb compound.
